(19) United States
(12) Patent Application Publication
(10) Pub. No.: US 2011/0272010 A1
(43) Pub. Date: Nov. 10, 2011

(54) HIGH WORK FUNCTION METAL INTERFACIAL FILMS FOR IMPROVING FILL FACTOR IN SOLAR CELLS

(75) Inventors: Ahmed Abou-Kandil, Elmsford, NY (US); Keith E. Fogel, Hopewell Junction, NY (US); Jeehwan Kim, Los Angeles, CA (US); Devendra K. Sadana, Pleasantville, NY (US)

(73) Assignee: INTERNATIONAL BUSINESS MACHINES CORPORATION, ARMONK, NY (US)

(21) Appl. No.: 12/776,549

(22) Filed: May 10, 2010

(51) Int. Cl. H01L 31/0224; H01L 31/18; H01L 31/0232

(52) U.S. Cl. 136/255; 136/261; 438/72; 257/E31.127; 257/E31.126

(57) ABSTRACT

A photovoltaic device and method include a doped transparent electrode, and a light-absorbing semiconductor structure including a first semiconductor layer. An ultra-thin layer of a non-transparent metal is formed between the transparent electrode and the first semiconductor layer to form a reduced barrier contact wherein the ultra-thin layer is light transmissive. When the ultrathin metal forms discrete individual dots, it permits a plasmonic light trapping effect to increase the current at solar cells.

### BACKGROUND

1. Technical Field

The present invention relates to photovoltaic devices, and more particularly to a device and method for improving performance by including high work function material in a photovoltaic device.

2. Description of the Related Art

Solar cells employ photovoltaic cells to generate current flow. Photons in sunlight hit a solar cell or panel and are absorbed by semiconducting materials, such as silicon. Carriers gain energy allowing them to flow through the material to produce electricity. Therefore, the solar cell converts the solar energy into a usable amount of electricity.

When a photon hits a piece of silicon, the photon may be transmitted through the silicon, the photon can reflect off the surface, or the photon can be absorbed by the silicon, if the photon energy is higher than the silicon band gap value. This generates an electron-hole pair and sometimes heat, depending on the band structure.

When a photon is absorbed, its energy is given to a carrier in a crystal lattice. Electrons in the valence band may be excited into the conduction band, where they are free to move within the semiconductor. The bond that the electron(s) were a part of form a hole. These holes can move through the lattice creating mobile electron-hole pairs.

A photon need only have greater energy than that of a band gap to excite an electron from the valence band into the conduction band. Since solar radiation is composed of photons with energies greater than the band gap of silicon, the higher energy photons will be absorbed by the solar cell, with some of the energy (above the band gap) being turned into heat rather than into usable electrical energy.

Referring to FIG. 1, a solar cell 10 may be formed on a glass substrate 8 and includes an electrode 12 separated from a p-type layer 14 by a Schottky or contact barrier 16 that forms. The electrode 12 includes a transparent thin film that is conductive, or a transparent conductive oxide (TCO). Currently developed TCOs are n-type since p-type states of TCO are thermodynamically unstable. Therefore, a Schottky barrier exits between the p-type layer 14 and the TCO 12. The p-type layer 14 and a TCO layer 20 are separated by an intrinsic layer 18 which typically provides for diffusion of electrons/holes which occurs from a region of high electron/hole concentration into the region of low electron/hole concentration. For amorphous phase materials, electron-hole pairs cannot diffuse from one end to the other end due to poor carrier life time so drift current is aided by the built-in potential field at the intrinsic layer. Because charge builds up, an electric field is created. The electric field forms a diode that promotes charge flow or drift current, that opposes and eventually balances out the diffusion of electrons and holes. A region where electrons and holes have diffused across the junction is called a depletion region since mobile charge carriers are no longer present.

Metal-semiconductor contacts 12, 22, and 24 are provided on both the n-type and p-type sides of the solar cell, and the electrodes may be connected to an external load. Contacts 22 and 24 include reflective surfaces to redirect any photons back into the semiconductor material. Contact 12 permits carriers to travel through a wire (not shown), power a load, and continue through the wire until they reach contact 22 (and 24). The metal-semiconductor contact between layer 12 and layer 14 forms a Schottky barrier 16. A Schottky barrier is a potential barrier formed at a metal-semiconductor junction which has rectifying characteristics like a diode. The Schottky barrier has a decreased depletion width in the metal.

The solar cell 10 may be described in terms of a fill factor (FF). FF is a ratio of the maximum power point (Pₘ) divided by open circuit voltage (V_{oc}) and short circuit current (I_{sc}):

$$FF = \frac{{P}_{m}}{{V}_{oc} {I}_{sc}} .$$

The fill factor is directly affected by the values of a cell's series and shunt resistance. Increasing the shunt resistance (Rₛₕ) and decreasing the series resistance (Rs) will lead to a higher fill factor, thus resulting in greater efficiency, and pushing the cells output power closer towards its theoretical maximum.

Referring to FIG. 2, the formation of the Schottky barrier at the interface or contact barrier 16 between layers 12 and 14 is difficult to avoid and overcome. The barrier forms as a result of the materials in contact (N-type metal and P-type semiconductor). Due to the N-type nature of TCO, the Schottky barrier always exists at the interface between the P-type semiconductor and TCO. In the example, a valence band edge of P-type amorphous silicon is located at ˜5.8 eV from vacuum and a work-function of aluminum doped ZnO (TCO) is ˜4.2 eV. Therefore, a Schottky barrier of ˜1.5 eV exists at the interface. Such barrier, when the band bending of semiconductors is straightened out near an open circuit voltage, increases series resistance by reducing the slope of a J-V curve of a pin diode. This accounts for a large portion of FF degradation. This problem becomes more severe when carbon is added into P-type layers, which further pushes the valence band edge further from vacuum.

Referring to FIG. 3, current density versus voltage (J-V curve) is plotted. The curve shows two areas 40 and 42 where current density falls off as a result of the Schottky barrier. A high contact barrier degrades fill factor of solar cells due to increased internal resistance.

### SUMMARY

A photovoltaic device and method include a transparent electrode. A light-absorbing semiconductor structure includes a first semiconductor layer. An ultra-thin layer of a non-transparent metal is formed between the transparent electrode and the first semiconductor layer to form an ohmic contact or to reduce a Schottky barrier. In a particularly useful embodiment, the ultra-thin layer of metal may include discontinuous nanodots or may include a continuous film of films. When the films formed are discontinuous nanodots, this offers a plasmonic light trapping effect so that current can be greater than that without using ultra-thin metals.

A photovoltaic device and method include a doped transparent electrode, and a light-absorbing semiconductor structure including a first semiconductor layer. An ultra-thin layer of a non-transparent metal is formed between the transparent electrode and the first semiconductor layer to form a reduced barrier contact wherein the ultra-thin layer is light transmissive. When the ultrathin metal forms discrete individual dots, it permits a plasmonic light trapping effect to increase the current at solar cells.

Another photovoltaic device includes a transparent electrode formed on a transmissive substrate. A light-absorbing semiconductor structure includes a P-type semiconductor layer, an intrinsic layer and an N-type semiconductor layer. An ultra-thin layer of a non-transparent metal is formed between the transparent electrode and the P-type semiconductor layer to form at least one of an ohmic contact and reduced barrier contact wherein the ultra-thin layer is light transmissive. A back-reflector forming a second electrode is formed on the N-type semiconductor layer.

A method for fabricating a photovoltaic device includes forming a doped transparent electrode on a transmissive substrate; forming an ohmic contact or reduced barrier contact by depositing an ultra-thin layer of a non-transparent metal having a thickness that enables light transmission therethrough; forming a light-absorbing semiconductor structure including a P-type semiconductor layer on the ultra-thin layer, an intrinsic layer and an N-type semiconductor layer; and forming a back-reflector on the N-type semiconductor layer to form a second electrode.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a solar collector having a Schottky barrier in accordance with the prior art;

FIG. 2 is a diagram showing a 1.5 eV off-set due to the Schottky barrier between a ZnO transparent electrode and a P-type layer in accordance with the prior art;

FIG. 3 is a plot of current density versus voltage showing Schottky barrier effects on the prior art device;

FIG. 4 is a cross-sectional view of a photovoltaic device having an ultra-thin metal layer to reduce effects due to the formation of a Schottky barrier in accordance with the present principles;

FIG. 5A is a diagram showing fill factor for different materials for the ultra-thin layer of 2 nm;

FIG. 5B is a diagram showing series resistance for different materials of the ultra-thin layer;

FIG. 6 is a plot of current density versus voltage showing improved current density as a result of the ultra-thin layer in accordance with the present principles; and

FIG. 7 is a block/flow diagram showing a method for fabricating a photovoltaic device with an ultra-thin layer in accordance with the present principles.

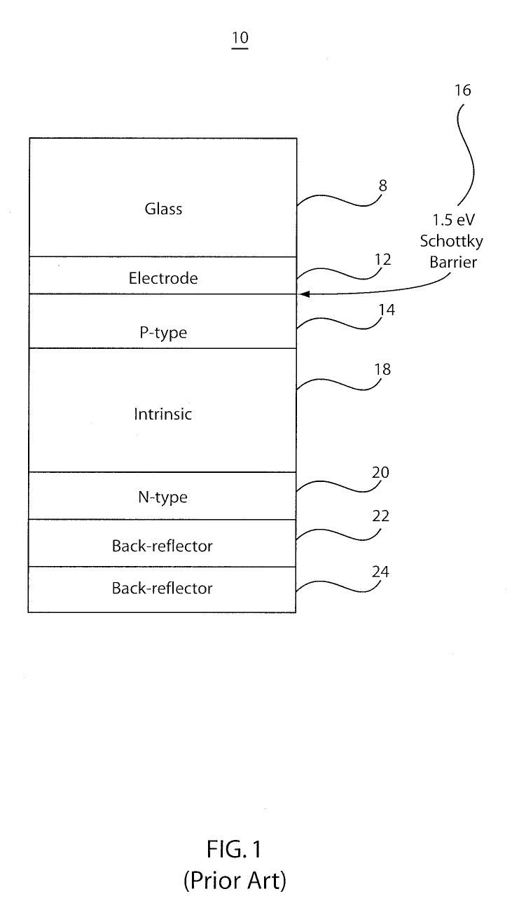

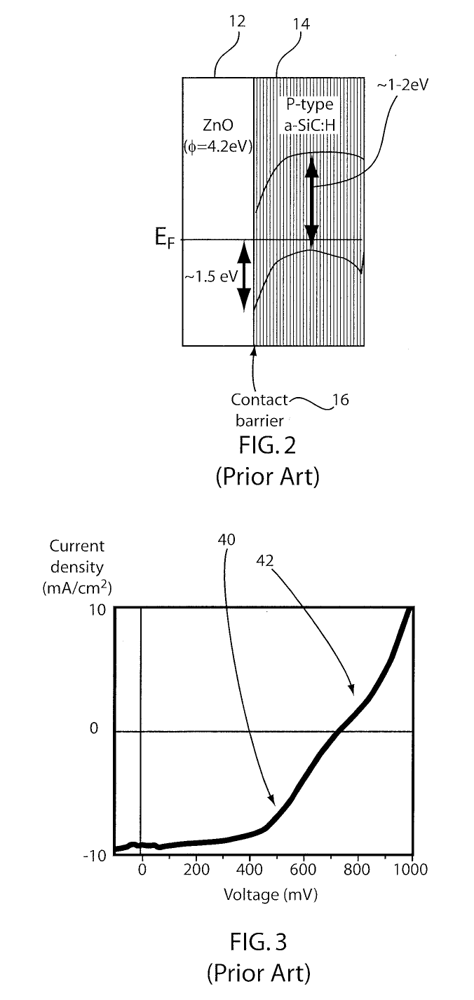

### DETAILED DESCRIPTION OF PREFERRED EMBODIMENTS

A photovoltaic device having an improved fill factor is provided. The photovoltaic device may include a solar cell. In addition, a method for forming a solar cell with an improved fill factor is disclosed. The solar cell reduces effects of the formation of a Schottky barrier by providing an ultra-thin conductive film between a metal contact and a semiconductor layer. Normally, the contact is a transparent conductive oxide (TCO), which permits light to transit therethrough. In accordance with one illustrative embodiment, a non-transparent metal is employed to form an ohmic contact or to reduce a Schottky barrier between the metal contact and the semiconductor material. The non-transparent metal is formed in a layer that is so thin (ultra-thin) that light can still be transmitted through it. When the ultra-thin metal layer is not continuous (nano-dots), it offers extra current due to plasmonic light trapping. The ohmic contact reduces or eliminates any Schottky effect or barrier hence improving the fill factor. Ultra-thin metal layers improve the fill factor as well as short circuit current.

It is to be understood that the present invention will be described in terms of a given illustrative architecture for a solar cell; however, other architectures, structures, substrate materials and process features and steps may be varied within the scope of the present invention. A circuit as described herein may be part of a design for an integrated circuit chip. The chip design may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips and/or solar cells. The resulting integrated circuit chips or cells can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes photovoltaic devices, integrated circuit chips with solar cells, ranging from toys, calculators, solar collectors and other low-end applications to advanced products.

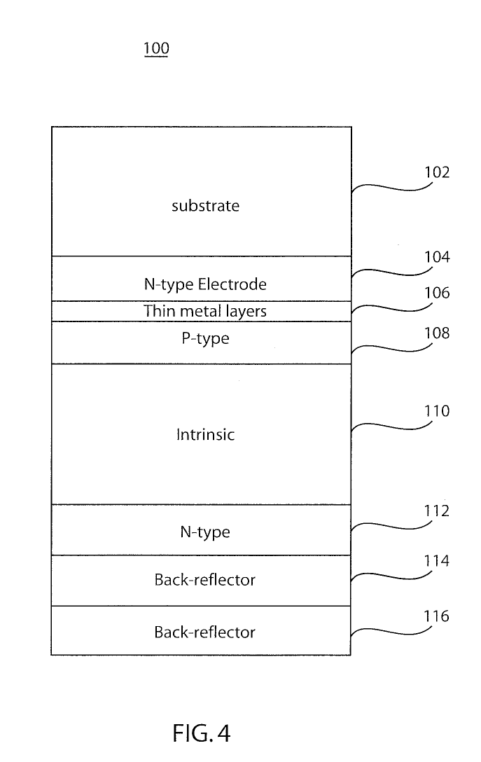

Referring now to the drawings in which like numerals represent the same or similar elements and initially to FIG. 4, an illustrative photovoltaic structure 100 is illustratively depicted in accordance with one embodiment. The photovoltaic structure 100 may be employed in solar cells, light sensors or other photovoltaic applications. Structure 100 includes a substrate 102 that permits a high-transmittance of light. The substrate 102 may include a transparent material, such as glass, a polymer, etc. or combinations thereof. A first electrode 104 includes a transparent conductive material. Electrode 104 preferably includes an N-type dopant, although a P-type dopants may also be employed. Electrode 104 may include a transparent conductive oxide (TCO), such as, e.g., a fluorine-doped tin oxide (SnO₂:F, or “FTO”), doped zinc oxide (e.g.,: ZnO:Al), and indium tin oxide (ITO) or other suitable materials. For the present example, a doped zinc oxide is illustratively employed for electrode 104. The TCO 104 permits light to pass through to an active light-absorbing material beneath and allows conduction to transport photo-generated charge carriers away from that light-absorbing material.

The light-absorbing material includes a P-type semiconductor layer 108. In this illustrative structure 100, layer 108 is formed on electrode 104. An intrinsic layer 110 of compatible material is formed on layer 108. Intrinsic layer 110 is undoped. An N-type layer 112 is formed on the intrinsic layer 110. The N-type layer 112 is in contact with a first back-reflector 114. The back-reflector 114 may be in contact with a second back-reflector 116. One of both of the back-reflectors 114 and 116 functions a second electrode.

The structure 100 is preferably a silicon thin-film cell, which includes silicon layers which may be deposited by a chemical vapor deposition (CVD) process, or a plasma-enhanced (PE-CVD)) from silane gas and hydrogen gas. Depending on the deposition parameters, amorphous silicon (a-Si or a-Si:H), and/or nanocrystalline silicon (nc-Si or nc-Si:H), also called microcrystalline silicon \textcircled{3}c-Si:H may be formed.

In one embodiment, structure 100 includes ZnO:Al for electrode 104, and P-type amorphous and microcrystalline silicon carbon (a+\textcircled{3}c)-SiC:H for layer 108. Intrinsic layer 110 includes amorphous silicon (a-Si:H), and layer 112 includes an N-type amorphous silicon (a-Si:H). The first back reflector 114 may include a transparent oxide, such as, ZnO, and the second back reflector 116 preferably includes a highly reflective material, such as silver (Ag), chromium (Cr), etc.

A layer 106 is formed between electrode 104 and layer 108 to avoid the formation of a diode-like Schottky barrier. In a first embodiment, a microcrystalline Si buffer is formed as a layer 106 between electrode 104 and layer 108 (which includes P-type a-SiC:H) for tunneling layers. However, when carbon content becomes too high the contact barrier becomes very difficult or impossible to overcome. Even with non-carbon doped Si, there exists a Schottky barrier. For example, a 1.85 eV band gap energy exists for slightly carbon-doped films. Without carbon doping, the band gap of a-Si:H is still 1.7˜1.8 eV so that a Schottky barrier would exist here as well.

In accordance with the present principles, the contact barrier problem is reduced or avoided by providing a material for layer 106 that has a high work function (e.g., highly conductive). Unfortunately, these types of materials are highly reflective and would reduce the absorption of radiation that is needed in a solar collector. Using an ultra-thin high work function metal, such as, Au, Ag, Pd, Pt, Al, Er, etc. or combinations thereof, layer 106 can be made thin enough to avoid transmittance loss. Layer 106 may include a metal layer of between about 0.1 nm and 20 nm. The metal layer 106 is preferably a P-type metal although N-type metals may also be employed (relative to the electrode 104). Forming layer 106 from an ultra-thin high-work function conductor, a direct removal or reduction of any contact barrier is achieved. High work function may be defined as a work-function higher than a work function of the transparent electrode 104 and close to the valance band edge of the p-type semiconductor 108. For example, in preferred embodiments the work-function may be from about 4.6 to about 6 eV).

In accordance with another embodiment, layer 106 may include a non-continuous layer of material. In one example, the ultra-thin metal may include nano-dots. Nano-dots can naturally occur under particular process conditions such as during an evaporation process where the thickness is sufficiently thin. When the metals form discontinuous dots, more current is permitted to flow than for solar cells without a metal layer 106. The nano-dots promote a plasmonic light trapping effect to assist in increasing current.

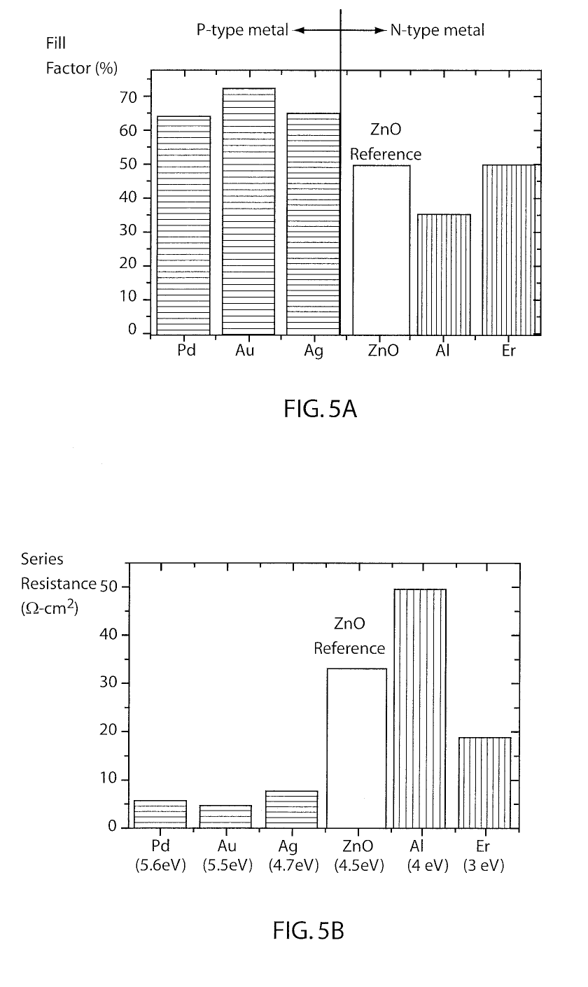

Referring to FIGS. 5A and 5B, illustrative results are shown for different materials. FIG. 5A shows Fill Factor (%) versus metal type for layer 106. Note that a ZnO reference is shown having FF=50%. Using Au at 2 nm thick, FF=72%. Note the P-type metals, Pd, Au and Ag show a significant improvement in FF, while Al shows a loss and Er is about the same as the reference. Note the metals were all 2 nm thick.

FIG. 5B shows series resistance versus materials. Each material includes its corresponding work function below it. As can be seen, the P-type metals provide a lower series resistance, which results in a high fill factor. Therefore, high work function (p-type relative to electrode 104) metals can be used to provide an ohmic contact or reduce a barrier to p-type a-SiC:H layers (and/or a-Si:H layers). In one example, when the thickness is ˜1 mm, the metal layer 106 is transparent enough to avoid light reflection. A 40% FF improvement is observed when Au is used.

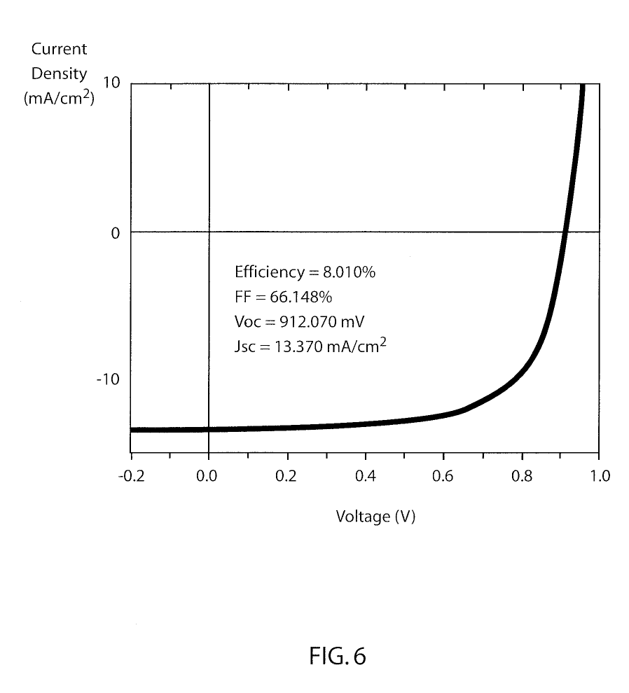

Referring to FIG. 6, current density is plotted versus voltage for a solar cell structure having a 1 nm Au layer 106. As can be seen from the plot, current density at short circuit (J_{sc}) is high at 13.370 mA/cm², and V_{oc}=912.070 mV. The fill factor=66.148%, and the efficiency was 8.010% even without using ZnO:Al back-reflectors.

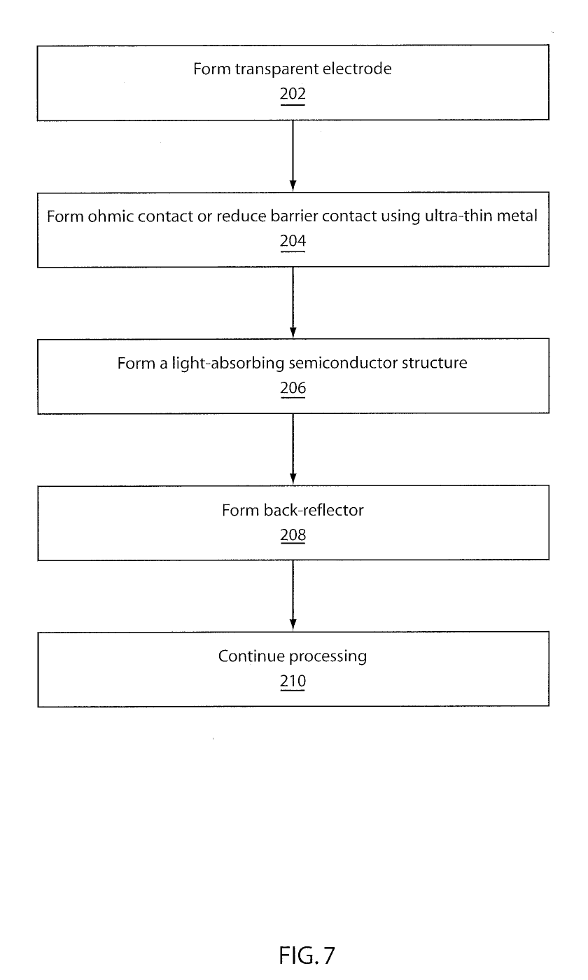

Referring to FIG. 7, a block/flow diagram shows a method for fabricating a photovoltaic device in accordance with one illustrative embodiment. In block 202, a doped transparent electrode is formed on a transmissive substrate. The transparent electrode may include an N-type or a P-type doping. The transmissive substrate may include a glass, polymer or other transmissive material. The transparent electrode may include doped zinc oxide, indium tin oxide, etc. In block 204, an ohmic contact or a reduced barrier contact is formed by depositing an ultra-thin layer of a non-transparent metal having a thickness that enables light transmission therethrough. The ultra-thin metal layer preferably includes a P-type metal, and may include a work function greater than the transparent electrode. The ultra-thin metal layer may include at least one of gold, silver, platinum and palladium. Other materials are also contemplated. The ultra-thin metal layer may include a thickness of between about 0.1 nm and about 20 nm.

In block 206, a light-absorbing semiconductor structure is formed. The semiconductor structure includes a P-type semiconductor layer on the ultra-thin layer, an intrinsic layer and an N-type semiconductor layer. The P-type semiconductor layer may include amorphous and microcrystalline Si or SiC. Other materials may also be employed. In block 208, a back-reflector is formed on the N-type semiconductor layer to form a second electrode. The back reflector may include more than one layer. In block 210, processing continues as is known in the art.

Having described preferred embodiments of a device and method for high work function metal interfacial films for improving fill factor in solar cells (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A photovoltaic device, comprising:
a doped transparent electrode;
a light-absorbing semiconductor structure including a first semiconductor layer; and
an ultra-thin layer of a non-transparent metal formed between the transparent electrode and the first semiconductor layer to form a reduced barrier contact wherein the ultra-thin layer is light transmissive.

2. The photovoltaic device as recited in claim 1, wherein transparent electrode includes a doped zinc oxide.

3. The photovoltaic device as recited in claim 1, wherein the first semiconductor layer includes at least one of Si, SiC, amorphous and microcrystalline SiC, and amorphous and microcrystalline Si.

4. The photovoltaic device as recited in claim 1, wherein the reduced barrier contact includes an ohmic contact.

5. The photovoltaic device as recited in claim 1, wherein the semiconductor structure further comprises an intrinsic layer and an additional semiconductor layer.

6. The photovoltaic device as recited in claim 1, further comprising at least one back-reflector layer coupled to the semiconductor structure on a side opposite the transparent electrode.

7. The photovoltaic device as recited in claim 1, wherein the ultra-thin metal layer includes high work function materials.

8. The photovoltaic device as recited in claim 1, wherein the ultra-thin metal layer includes a work function greater than the transparent electrode.

9. The photovoltaic device as recited in claim 1, wherein the ultra-thin metal layer includes at least one of gold, platinum, silver and palladium.

10. The photovoltaic device as recited in claim 1, wherein the ultra-thin metal layer includes a thickness of between about 0.1 nm and about 20 nm.

11. The photovoltaic device as recited in claim 1, wherein the ultra-thin metal layer includes a discontinuous layer of nano-dots.

12. The photovoltaic device as recited in claim 1, wherein the first semiconductor layer includes a material whose valence band edge is located lower than a work-function of the transparent electrode.

13. A photovoltaic device, comprising:
a transparent electrode formed on a transmissive substrate;
a light-absorbing semiconductor structure including a P-type semiconductor layer, an intrinsic layer and an N-type semiconductor layer;
an ultra-thin layer of a non-transparent metal formed between the transparent electrode and the P-type semiconductor layer to form at least one of an ohmic contact and reduced barrier contact wherein the ultra-thin layer is light transmissive; and
a back-reflector forming a second electrode and formed on the N-type semiconductor layer.

14. The photovoltaic device as recited in claim 13, wherein transparent electrode includes doped zinc oxide.

15. The photovoltaic device as recited in claim 13, wherein the P-type semiconductor layer includes a material whose valence band edge is located lower than a work-function of the transparent electrode.

16. The photovoltaic device as recited in claim 13, wherein the P-type semiconductor layer includes at least one of Si, SiC, a-SiC:H, and a-Si:H.

17. The photovoltaic device as recited in claim 13, wherein the ultra-thin metal layer includes a work function greater than the transparent electrode.

18. The photovoltaic device as recited in claim 13, wherein the ultra-thin metal layer includes at least one of gold, silver, platinum and palladium.

19. The photovoltaic device as recited in claim 13, wherein the ultra-thin metal layer includes a thickness of between about 0.1 nm and about 20 nm.

20. The photovoltaic device as recited in claim 13, wherein the ultra-thin metal layer includes a discontinuous layer of nano-dots.

21. A method for fabricating a photovoltaic device, comprising:
forming a doped transparent electrode on a transmissive substrate;
forming an ohmic contact or reduced barrier contact by depositing an ultra-thin layer of a non-transparent metal having a thickness that enables light transmission therethrough;
forming a light-absorbing semiconductor structure including a P-type semiconductor layer on the ultra-thin layer, an intrinsic layer and an N-type semiconductor layer; and
forming a back-reflector on the N-type semiconductor layer to form a second electrode.

22. The photovoltaic device as recited in claim 21, wherein the P-type semiconductor layer includes at least one of Si, SiC, a-SiC:H, and a-Si:H.

23. The method as recited in claim 21, wherein the ultra-thin metal layer includes a discontinuous layer of nano-dots.

24. The method as recited in claim 21, wherein the ultra-thin metal layer includes a work function greater than the transparent electrode.

25. The method as recited in claim 19, wherein the ultra-thin metal layer includes a thickness of between about 0.1 nm and about 20 nm.
